(19) United States
(12) Patent Application Publication
(10) Pub. No.: US 2012/0200546 A1
(43) Pub. Date: Aug. 9, 2012

(54) SEMICONDUCTOR DEVICE, DISPLAY DEVICE PROVIDED WITH SAME, AND METHOD FOR MANUFACTURING SEMICONDUCTOR DEVICE

(75) Inventors: Tadayoshi Miyamoto, Osaka (JP); Kazuhide Tomiyasu, Osaka (JP); Sumio Katoh, Osaka (JP)

(73) Assignee: SHARP KABUSHIKI KAISHA, Osaka (JP)

(21) Appl. No.: 13/501,830

(22) PCT Filed: Jun. 7, 2010
(86) PCT No.: PCT/JP2010/059598

§ 371 Date: Apr. 13, 2012

(30) Foreign Application Priority Data
Oct. 16, 2009 (JP) 2009-239383

(51) Int. Cl. G06F 3/038; H01L 21/20; H01L 29/786

(52) U.S. Cl. 345/205; 257/66; 438/486; 257/E29.273; 257/E21.09

(57) ABSTRACT

Disclosed is a semiconductor device including plural types of semiconductor elements having structures that have respective thicknesses suitable for their uses formed in the same process. A semiconductor device (100) includes a TFT (40) and a photodiode (50). A gate electrode (110) of the TFT (40) and a light-shielding layer (60) of the photodiode (50) are formed in the same process. However, because the film thickness of the gate electrode (110) is small, the breakage of an island-shaped silicon layer (120), which will be the channel layer, at the edge of the gate electrode (110) can be prevented. Also, because the film thickness of the light-shielding layer (60) is large, the light entering through a surface of a glass substrate (101) on the side opposite from the surface on which the TFT is formed can be reliably blocked by the light-shielding layer (60). Consequently, the detection sensitivity of the photodiode (50) can be increased.

### TECHNICAL FIELD

The present invention relates to a semiconductor device, a display device equipped with the semiconductor device, and a method for manufacturing the semiconductor device. More particularly, the present invention relates to a semiconductor device in which multiple types of semiconductor elements are formed on the same insulating substrate, a display device equipped with the semiconductor device, and a method for manufacturing the semiconductor device.

### BACKGROUND ART

In recent years, development of active matrix type liquid crystal display devices including a liquid crystal panel having a touch-panel feature has been underway. For such liquid crystal panels of liquid crystal display devices, in each of the pixel formation sections formed in the display region where images are displayed, a thin film transistor (hereinafter referred to as “TFT”) that functions as a switching element and a photodiode that functions as a touch sensor are provided. Also, in the frame region that borders the display region, a gate driver, source driver, and the like constituted of TFTs are increasingly formed recently.

Patent Document 1 describes a liquid crystal panel on which photodiodes that function as touch sensors and TFTs that function as switching elements of the pixel formation sections are formed on the same transparent substrate. The channel layer of the TFT is composed of a crystalline silicon layer, which is made by crystallizing an amorphous silicon layer. The gate electrode is formed over the channel layer. On the other hand, the photodiode is a pn junction diode where an n-type silicon region and a p-type silicon region, which are made of amorphous silicon formed simultaneously with the TFT channel layer, are joined together. Below the photodiode, a light-shielding layer is formed on the glass substrate to prevent the light from the backlight light source from entering the photodiode.

Thus, because the gate electrode of TFT is formed over the silicon layer and the light-shielding layer is formed below the silicon layer, the gate electrode and the light-shielding layer cannot be formed in the same process. This makes the manufacturing process of liquid crystal panel complex and increases the manufacturing cost.

In order to form the gate electrode of TFT and the light-shielding layer in the same process, the TFT discussed in Patent Document 1 is replaced with a bottom gate type TFT in which the gate electrode is formed on the glass substrate. This way, the gate electrode of TFT and the light-shielding layer can be formed in the same process, the manufacturing process of the liquid crystal panel can be simplified, and the manufacturing cost can be reduced.

### RELATED ART DOCUMENTS

### Patent Documents

Patent Document 1: Japanese Patent Application Laid-Open Publication No. 2009-128520

### SUMMARY OF THE INVENTION

### Problems to be Solved by the Invention

However, because the gate electrode of TFT and the light-shielding layer are formed simultaneously, the film thickness of the gate electrode and the film thickness of the light-shielding layer become equal. As the film thickness of the gate electrode increases, so does the surface elevation of the edge of the gate electrode from the glass substrate. Therefore, the surface elevation of the amorphous silicon layer, which is formed to cover the gate electrode, also becomes larger at the edge of the gate electrode. To convert the amorphous silicon layer into a polycrystalline silicon layer, a laser light is radiated over the top surface of the amorphous silicon layer to melt the amorphous silicon layer. The melted silicon flows towards the glass substrate side and is solidified to become a polycrystalline silicon layer. In this case, the polycrystalline silicon layer can break at the edge of the gate electrode due to the difference in level, which makes the polycrystalline silicon layer unusable as the channel layer of TFT.

Also, the energy of the laser light radiated over the amorphous silicon layer becomes the thermal energy. If the gate electrode is made of a material of high thermal conductivity, part of the thermal energy is lost to the gate wiring through the gate electrode. The amorphous silicon layer, therefore, cannot be maintained at a high temperature for extended period of time. As a result, the crystal grains of the polycrystalline silicon layer do not grow large enough, and the mobility of the polycrystalline silicon layer is reduced.

On the other hand, if the film thickness of the light-shielding layer of the photodiode is too small, the light from the backlight light source cannot be sufficiently blocked, and the photodiode detects the light projected directly from the backlight light source also. As a result, the light that is delivered from the backlight light source and is reflected by a finger or the like is not detected with sufficient sensitivity.

When the gate electrode of the TFT and the light-shielding layer of the photodiode are formed from the same layer of a conductive film, their film thicknesses become equal. This means that the film thickness may be optimal for the gate electrode of TFT, but may not be for the light-shielding layer of the photodiode, or, conversely, may be optimal for the light-shielding layer of the photodiode, but may not be for the gate electrode of TFT.

On the other hand, if the gate electrode of the bottom gate type TFT and the light-shielding layer of the photodiode are formed in different processes, both the gate electrode and the light-shielding layer will have their own optimal film thickness. However, this makes the manufacturing process of the liquid crystal panel complex, and increases the manufacturing cost.

An object of the present invention, therefore, is to provide a semiconductor device that includes multiple types of semiconductor elements each having a thickness suitable to its use and having a structure that is formed in the same process. Another objective of the present invention is to simplify the manufacturing process for such a semiconductor device and to provide a method for manufacturing such a semiconductor at a low cost.

### Means for Solving the Problems

Aspect 1 of the present invention is a semiconductor device including at least a first semiconductor element and a second semiconductor element whose type is different from that of the first semiconductor element, both formed on the same insulating substrate,

wherein the first semiconductor element includes:

a first structure having a surface elevation and constituted of a first layer; and

a polycrystalline semiconductor layer covering at least the surface elevation of the first structure,

wherein the second semiconductor element includes a second structure including a second layer made of the same material as the first layer, the second structure being thicker than the first structure, and

wherein the surface elevation of the first structure is such that the polycrystalline semiconductor layer is formed without any breakage.

Aspect 2 of the present invention is Aspect 1 of the present invention, wherein at least the surface elevation of the first structure has a tapered edge.

Aspect 3 of the present invention is Aspect 1 of the present invention,

wherein the first semiconductor element is a bottom gate type thin film transistor, the first structure is a gate electrode of the bottom gate type thin film transistor, and the polycrystalline semiconductor layer is a channel layer of the bottom gate type thin film transistor, and

wherein the second semiconductor element is a light sensor that receives light entering through a first surface of the insulating substrate, on which surface the bottom gate type thin film transistor is formed, and

wherein the second structure is a light-shielding layer that, in the insulating substrate, blocks light projected through a second surface that faces the first surface from entering the light sensor.

Aspect 4 of the present invention is Aspect 3 of the present invention,

wherein the light-shielding layer is constituted only of the second layer, and

wherein the film thickness of the second layer is larger than the film thickness of the gate electrode.

Aspect 5 of the present invention is Aspect 3 of the present invention,

wherein the light-shielding layer is constituted of a plurality of layers including the second layer, and

wherein the film thickness of the second layer is equal to the film thickness of the gate electrode.

Aspect 6 of the present invention is Aspect 3 of the present invention, wherein the channel layer is a polycrystalline semiconductor layer that includes lateral crystals whose direction of long axis matches the direction of channel length.

Aspect 7 of the present invention is Aspect 3 of the present invention, wherein the light sensor is a lateral type pin photodiode.

Aspect 8 of the present invention is Aspect 3 of the present invention, further including a wiring connected to the gate electrode of the thin film transistor, wherein the wiring includes a third layer disposed on the top surface of the first layer and made of a material with conductivity higher than that of the first layer.

Aspect 9 of the present invention is a display device including a plurality of pixel formation sections disposed on an insulating substrate, each of the pixel formation sections having the semiconductor device according to Aspect 3,

wherein each of the plurality of pixel formation sections includes:

a pixel electrode;

a thin film transistor that applies a voltage on the pixel electrode when being switched from OFF state to ON state; and

a first light sensor that receives the light entering the pixel formation section, and

wherein the thin film transistor and the first light sensor are the first semiconductor element and the second semiconductor element, respectively.

Aspect 10 of the present invention is Aspect 9 of the present invention, further including a driver circuit that drives the pixel formation sections, wherein the driver circuit is constituted of the first semiconductor elements.

Aspect 11 of the present invention is Aspect 9 of the present invention, further including:

a backlight light source;

a second light sensor that is disposed outside the display region in which the plurality of pixel formation sections are formed, the second light sensor detecting external light intensity; and

a backlight control circuit that controls a luminance of the backlight light source based on an output from the second light sensor,

wherein the second light sensor is the second semiconductor element.

Aspect 12 of the present invention is a method for manufacturing a semiconductor device in which a bottom gate type thin film transistor and a light sensor having a light-shielding layer are formed on the same insulating substrate, including:

depositing a first conductive layer on the insulating substrate;

depositing a second conductive layer on the first conductive layer;

forming a first resist pattern in a region on the second conductive layer that will be a gate electrode, and forming a second resist pattern having a larger film thickness than the first resist pattern in a region on the second conductive layer that will be a light-shielding layer by conducting an exposure using a halftone mask;

forming the light-shielding layer by etching the second conductive layer and the first conductive layer in this order using the first and second resist patterns;

exposing a surface of the second conductive layer, which was covered with the first resist pattern, by reducing the film thicknesses of the first and second resist patterns simultaneously; and

forming the gate electrode by removing the second conductive layer the surface of which has been exposed.

Aspect 13 of the present invention is Aspect 12 of the present invention, further including:

forming an amorphous semiconductor layer to cover the gate electrode and the light-shielding layer;

forming a polycrystalline semiconductor layer by first melting the amorphous semiconductor layer by radiating continuous-wave laser light and then solidifying the melted amorphous semiconductor layer; and

patterning the polycrystalline semiconductor layer to form a channel layer of the thin film transistor that covers the gate electrode and a semiconductor layer of the light sensor over the light-shielding layer simultaneously.

### Effects of the Invention

In Aspect 1 of the present invention, in the first semiconductor element, a polycrystalline layer is formed to cover at least the surface elevation of the first structure, and the surface elevation of the first structure does not cause breakage of the polycrystalline semiconductor layer when the polycrystalline semiconductor layer is formed. As a result, failure of the first semiconductor element due to the breakage of the polycrystalline semiconductor layer can be prevented. On the other hand, in the second semiconductor element, because the thickness of the second structure is larger than the thickness of the first structure, the second structure can be used as the light-shielding layer or as a wiring with low wiring resistance.

In Aspect 2 of the present invention, because the surface elevation of the first structure has a tapered edge, the surface elevation of the first structure is less likely to cause breakage of the polycrystalline semiconductor layer. As a result, failure of the first semiconductor element due to the breakage of the polycrystalline semiconductor layer can be prevented even more effectively.

In Aspect 3 of the present invention, in the bottom gate type thin film transistor, the channel layer is formed of the polycrystalline semiconductor layer. As a result, the mobility of the channel layer increases, and therefore the bottom gate type thin film transistor can operate at a higher speed. Also, because the breakage of the polycrystalline silicon layer at the edge of the gate electrode can be prevented, the bottom gate type thin film transistor can operate reliably. In the light sensor, the light-shielding layer can block the light entering through a second surface of the insulating substrate, which is on the side opposite from the first surface of the insulating substrate on which the bottom gate type thin film transistor is formed. Therefore, if the light sensor is used as a touch sensor, the detection sensitivity of the light sensor can be increased.

According to Aspect 4 of the present invention, because the light-shielding layer is constituted only of the second layer that is made of the same material as the gate electrode, the light-shielding layer can easily be deposited. Also, because the second layer has a larger film thickness than the gate electrode, the light-shielding layer can block the light entering from the second surface side.

According to Aspect 5 of the present invention, because the light-shielding layer is composed of multiple layers including the second layer having the same film thickness as the gate electrode, the light entering from the second surface side can be blocked more effectively.

According to Aspect 6, because the channel layer of the bottom gate type thin film transistor is a polycrystalline semiconductor layer containing lateral crystals with large crystal grain diameters and having a direction of long axis that matches the direction of channel length, the mobility of the channel layer increases. As a result, the bottom gate type thin film transistor can operate at a higher speed.

In Aspect 7 of the present invention, the light sensor is a lateral type pin photodiode. As a result, a higher quantum efficiency and a faster response time of the light sensor can be obtained.

In Aspect 8 of the present invention, the wiring connected to the gate electrode of the bottom gate type thin film transistor includes a third layer, which has a higher conductivity than the first layer, on the top surface of the first layer. As a result, delay in signals provided to the gate electrode through the wiring can be prevented.

In Aspect 9 of the present invention, by using the bottom gate type thin film transistor, which is the first semiconductor element of the semiconductor device according to Aspect 3, as the thin film transistor included in each of the pixel formation sections formed on the insulating substrate, and by using the light sensor, which is the second semiconductor element of the semiconductor device, as the first light sensor, the thin film transistor can operate at a high speed, and the detection sensitivity of the first light sensor can be increased. As a result, a touch panel feature can be provided to the display device.

In Aspect 10 of the display device, by forming the driver circuit for driving the pixel formation sections of the display device using the bottom gate type thin film transistor, which is the first semiconductor element of the semiconductor device according to Aspect 3, the thin film transistor can operate at a higher speed, and the driver circuit can also operate at a higher speed accordingly.

In Aspect 11 of the present invention, in the display device, a second light sensor that detects external light intensity is provided. By using the light sensor that is the second semiconductor element of the semiconductor device according to Aspect 3 as the second light sensor, the intensity of external light can be detected without being affected by the light from the backlight light source. Therefore, the second light sensor can function as an ambient sensor. As a result, the display device can adjust the illuminance of the backlight light source according to the intensity of external light.

In Aspect 12 of the present invention, with the photolithography using a halftone mask, the first resist pattern is formed in the region that will be the gate electrode, and the second resist pattern, whose film thickness is larger than that of the first resist pattern, is formed in the region that will be the light-shielding layer. The multi-layered film is etched using the first and second resist patterns as masks. As a result, the light-shielding layer is formed. Further, by reducing the film thicknesses of the first and second resist patterns simultaneously, the first resist pattern is removed and the surface of the second conductive layer in the region that will be the gate electrode is exposed. Next, while the second resist pattern is still preserved, the second conductive layer whose surface has been exposed is removed to form the gate electrode. Thus, the gate electrode and the light-shielding layer, which have different film thicknesses, can be formed by a single photolithography process by utilizing the difference in the film thickness between the first resist pattern and the second resist pattern, which are formed using the halftone mask. As a result, the semiconductor device can be manufactured in a simpler manner, and the manufacturing cost can be reduced accordingly.

In Aspect 13 of the present invention, the deposited amorphous semiconductor layer is irradiated with laser light of the continuous-wave laser to be converted to a polycrystalline semiconductor layer. The crystal grains of the polycrystalline semiconductor layer formed this way are lateral crystals, and therefore the polycrystalline semiconductor layer obtains a high mobility. As a result, the thin film transistor can operate a high speed.

### BRIEF DESCRIPTION OF THE DRAWINGS

FIG. 1 is a perspective view illustrating the configuration of a liquid crystal panel that has a touch panel feature and is included in an active matrix type liquid crystal display device according to an embodiment of the present invention.

FIG. 2 is a circuit diagram showing the configuration of the display region of the liquid crystal panel.

FIG. 3 is a cross-sectional view showing a cross section of the display region of the liquid crystal panel shown in FIG. 1.

FIG. 4 is a plan view showing the configuration of a bottom gate type TFT and a photodiode included in a semiconductor device of the present invention.

FIG. 5 is a cross-sectional view showing the configuration of the semiconductor device shown in FIG. 4.

FIG. 6(A) to FIG. 6(F) are cross-sectional views showing manufacturing steps of the semiconductor device shown in FIG. 5.

FIG. 7(G) to FIG. 7(J) are cross-sectional views showing manufacturing steps of the semiconductor device shown in FIG. 5.

FIG. 8 illustrates the mobility of polycrystalline silicon layers crystallized by using the continuous-wave laser and the excimer laser.

FIG. 9 is a cross-sectional view showing the configuration of a semiconductor device according to Modification Example 1 of the present invention, where the semiconductor device includes a TFT having a gate electrode with tapered edges.

FIG. 10 is a cross-sectional view showing the configuration of the semiconductor device according to Modification Example 3 of the present invention, where the semiconductor device includes a double gate type TFT.

FIG. 11 is a perspective view showing the configuration of a liquid crystal panel according to Modification Example 4 of the present invention, where the liquid crystal panel includes a photodiode that functions as an ambient light sensor.

### DETAILED DESCRIPTION OF EMBODIMENTS

### 1. Liquid Crystal Display Device

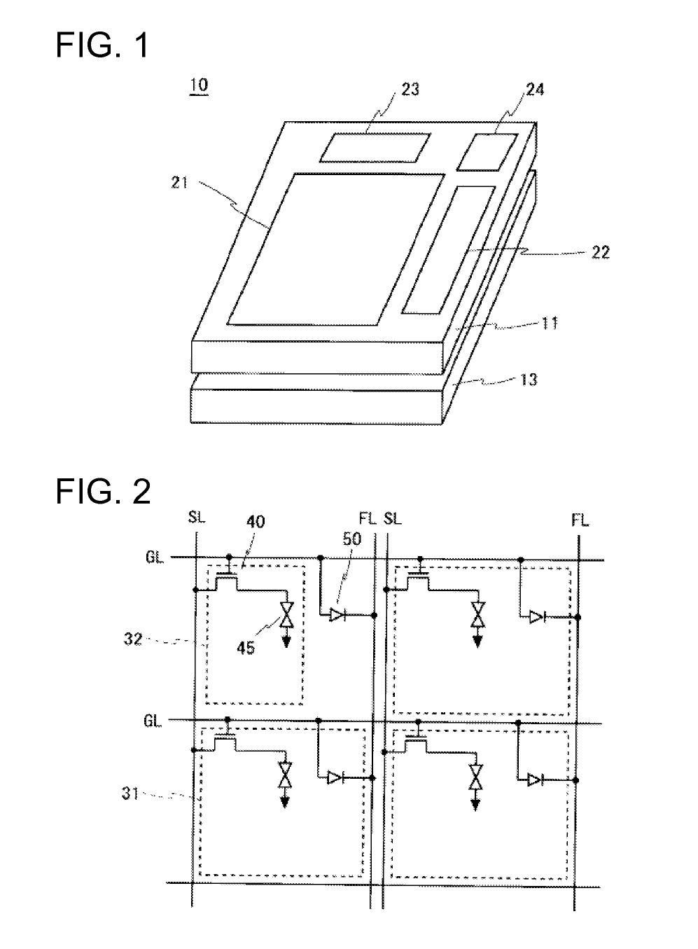

FIG. 1 is a perspective view illustrating the configuration of a liquid crystal panel 10 having a touch panel feature, which is included in an active matrix type liquid crystal display device according to an embodiment of the present invention. FIG. 1 shows a substrate 11, one of the two low-alkaline glass substrates disposed facing each other to sandwich a liquid crystal layer (hereinafter referred to as “glass substrate”), on which a plurality of pixel formation sections each containing a TFT, a photodiode, and the like are formed in a matrix (hereinafter referred to as “TFT substrate 11”), and a backlight light source 13, which is disposed facing the back side of the TFT substrate 11 (bottom side of FIG. 1). However, the glass substrate disposed facing the front side of the TFT substrate 11 (top side of FIG. 1), on which a color filter and the like are formed (CF substrate), and the liquid crystal layer sandwiched between the TFT substrate 11 and the CF substrate are omitted in the figure.

As shown in FIG. 1, in the middle area of the TFT substrate 11, a display region 21 composed of a plurality of pixel formation sections to display images is formed. In each of the pixel formation sections, as described later, a TFT that functions as the switching element and a photodiode that functions as the touch sensor are formed. Provided in the frame region bordering the display region 21 are a gate driver 22 that outputs to the gate wiring a control signal for controlling the timing with which the TFTs are turned on and off, a source driver 23 that outputs to the source wiring the image signal for displaying images on the pixel formation sections and a control signal for controlling the timing with which the control signal is outputted (the gate driver and the source driver are sometimes collectively called “driver circuit”), and a location detecting circuit 24 that detects the location of a touch on the liquid crystal panel 10 based on the detected light intensity at the photodiode.

FIG. 2 is a circuit diagram showing the configuration of the display region 21 of the liquid crystal panel 10. The liquid crystal panel 10 includes a plurality of pixel formation sections 31, a plurality of gate wirings GL, a plurality of source wirings SL, and a plurality of sensor wirings FL formed on the glass substrate (not shown). The source wirings SL and the sensor wirings FL are disposed alternately and in parallel with each other. The gate wirings GL are disposed in the direction that crosses the source wirings SL and the sensor wirings FL.

The pixel formation section 31 is disposed near the intersection of a gate wiring GL and a source wirings SL, and includes a liquid crystal cell 32 and a photodiode 50. The liquid crystal cell 32 displays images by adjusting the amount of the transmitted light from the backlight light source 13. The photodiode 50 detects the light that is projected from the backlight light source 13 and enters the pixel formation section 31 after being reflected by a finger, a touch pen, or the like (these may collectively be called “contact object”).

The liquid crystal cell 32 includes a TFT 40 that functions as the switching element and a pixel capacitance 45. The gate electrode of the TFT 40 is connected to the gate wiring GL, the source electrode is connected to the source wirings SL, and the drain electrode is connected to the pixel electrode (not shown). The pixel capacitance 45 is composed of a pixel electrode, an opposite electrode (not shown) formed on the CP substrate to face the pixel electrode, and a liquid crystal layer sandwiched between these electrodes. The photodiode 50 is disposed near the intersection of a gate wiring GL and a sensor wiring FL. The anode electrode of the photodiode 50 is connected to the gate wiring GL, and the cathode electrode is connected to the sensor wiring FL.

When the gate wirings GL are activated sequentially, the TFT 40 connected to the activated gate wiring GL is turned on. Then, the signal voltage of the image signal provided to the source wirings SL is supplied to the drain electrode through the TFT 40, and is stored in the pixel capacitance 45. Next, according to the signal voltage stored, the light from the backlight light source 13 is transmitted through the liquid crystal cell 32 to display an image in the display region 21 of the liquid crystal panel 10.

When a prescribed voltage is applied on the gate wiring GL, the current corresponding to the intensity of the light that entered the photodiode 50 flows from the gate wiring GL to the sensor wiring FL through the photodiode 50. The location detecting circuit 24 detects the intensity of the light received by the photodiode 50 by detecting the current that flows into the sensor wiring FL to determine the location of a touch on the CF substrate.

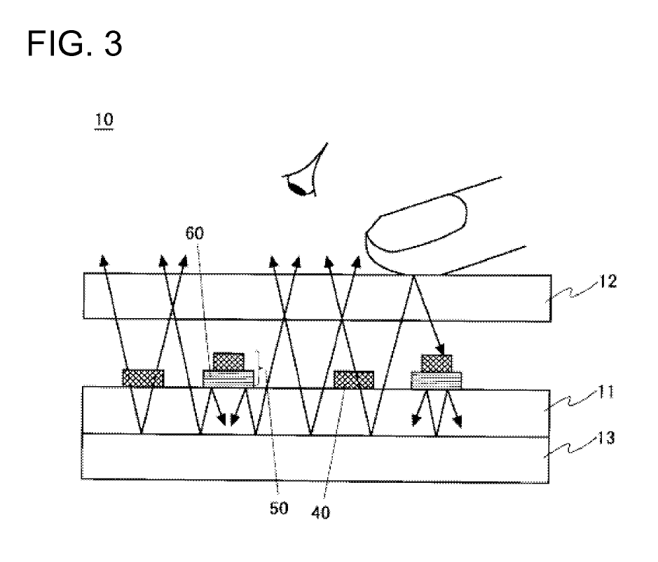

FIG. 3 is a cross-sectional view showing a cross section of the display region 21 of the liquid crystal panel 10 shown in FIG. 1. As shown in FIG. 3, the liquid crystal panel 10 includes a TFT substrate 11 on which a TFT 40 and a photodiode 50 are formed in each of the pixel formation sections 31, a CF substrate 12 disposed facing the TFT substrate 11 and having a color filter and the like formed thereon, a liquid crystal layer (not shown) sandwiched between the TFT substrate 11 and the CF substrate 12, and a backlight light source 13 disposed facing the TFT substrate 11 on the side opposite from the CF substrate 12. The light from the backlight light source 13 is transmitted through the TFT substrate 11, the liquid crystal layer, and the color filter of the CF substrate 12 (not shown) in this order, and the amount of the light transmitted is adjusted to the amount corresponding to the signal voltage stored at the pixel capacitance. Thus, images are displayed on the display region 21.

In the liquid crystal panel 10 discussed above, a light-shielding layer 60 is formed under the photodiode 50 on the TFT substrate 11. As a result, the light from the backlight light source 13 is reflected by the light-shielding layer 60, and therefore does not enter the light-receiving surface of the photodiode 50. However, when a user touches the surface of the CF substrate 12 with a finger or the like, the light from the backlight light source 13 that passed through the CF substrate 12 is reflected by the finger or the like and enters the light-receiving surface of the photodiode 50. Consequently, the photodiode 50 disposed below the location of the touch receives only the light reflected by the finger or the like, which makes the location detecting circuit 24 to easily determine the location of the touch. Thus, in order to facilitate the detection by the photodiode 50 of the light reflected by the finger or the like, the light-shielding layer 60 must be formed to at least a sufficient film thickness to prevent the light from the backlight light source 13 from entering the photodiode 50 directly, and also be formed to cover an area larger than the photodiode 50 when observed in a plan view.

### 2. Configuration of the Semiconductor Device

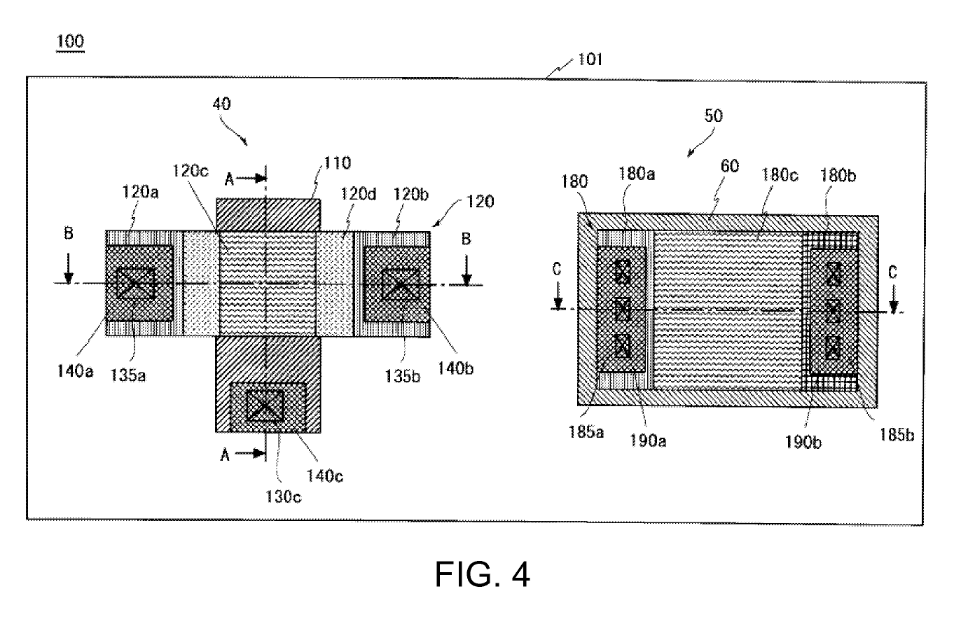

FIG. 4 is a plan view showing the configuration of a bottom gate type TFT 40 (hereinafter referred to as “TFT 40”) included in the semiconductor device 100 according to an embodiment of the present invention. In FIG. 4, one TFT 40 and one photodiode 50 are disposed on the glass substrate 101. However, a plurality of each of them may be disposed.

First, the configuration of the TFT 40 is described. As shown in FIG. 4, a gate electrode 110 is formed on the glass substrate 101. Edges of the gate electrode 110 are formed to be approximately normal to the glass substrate 101. Over the gate electrode 110, an island-shaped silicon layer 120 that functions as the channel layer in the direction perpendicular to the gate electrode 110 is formed through a gate insulating film (not shown). The island-shaped silicon layer 120 is made of a polycrystalline silicon layer, which was crystallized by conducting a laser-annealing process on an amorphous silicon layer. A source region 120a and a drain region 120b, which are doped with an n-type purity at a high concentration, are formed at the left and right ends of the island-shaped silicon layer 120, respectively. A channel layer 120c is formed in a region located above the gate electrode 110 and sandwiched by the source region 120a and the drain region 120b. The source region 120a and the drain region 120b are electrically connected to the source electrode 140a and the drain electrode 140b, respectively, through contact holes 135a and 135b formed in the interlayer insulating film (not shown). The source electrode 140a is electrically connected to the source wirings (not shown), and the drain electrode 140b is electrically connected to the pixel electrode (not shown). Also, one end of the gate electrode 110 is electrically connected to the gate connection electrode 140c through the contact hole 130c, and the gate connection electrode 140c is electrically connected to the gate wiring (not shown).

Next, the photodiode 50 is described. A light-shielding layer 60 is formed on the glass substrate 101. The light-shielding layer 60 is formed of a multi-layered metal film, which is composed of a first metal layer with a second metal layer disposed thereon to block the light from the backlight light source. The material and the film thickness of the first metal layer are the same as the material and the film thickness of the gate electrode 110. Over the light-shielding layer 60, an island-shaped silicon layer 180 is formed through the gate insulating film such that at least it does not extend beyond the light-shielding layer 60. The island-shaped silicon layer 180 is made of the polycrystalline silicon layer formed in the same process as the island-shaped silicon layer 120 of the TFT 40.

At left and right ends of the island-shaped silicon layer 180, an n-type region 180a, which is doped with an n-type impurity at a high concentration, and a p-type region 180b, which is doped with a p-type impurity at a high concentration, are formed, respectively. An intrinsic region 180c is formed in a region sandwiched by the n-type region 180a and the p-type region 180b. The n-type region 180a and the p-type region 180b are electrically connected to the cathode electrode 190a and the anode electrode 190b, respectively, through contact holes 185a and 185b formed in the interlayer insulating film. The photodiode 50 is a lateral-type pin diode having a high quantum efficiency and featuring a fast response time. However, it may be a pn junction diode in which the p-type region and the n-type region are directly joined together. The n-type region 180a, intrinsic region 180c, and the p-type region 180b of the lateral-type pin diode are sometimes collectively called “semiconductor layer.”

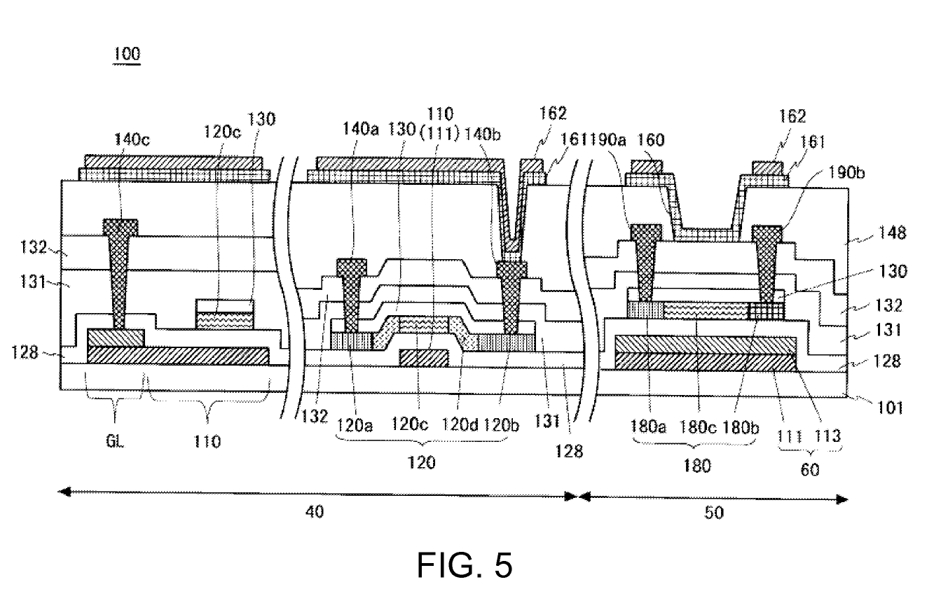

FIG. 5 is a cross-sectional view showing the configuration of the semiconductor device 100 shown in FIG. 4. FIG. 5 shows cross-sectional views of the TFT 40 and the photodiode 50 of FIG. 4, which are, from left, the TFT 40 taken along the line A-A, the TFT 40 taken along the line B-B, and the photodiode 50 taken along the line C-C.

On the glass substrate 101, which is an insulating substrate, the gate electrode 110 of the TFT 40 and the light-shielding layer 60 of the photodiode 50 are formed. In consideration of the heat treatment conducted later in the manufacturing process, the material for the gate electrode 110 is preferably a metal with a high melting point, such as tungsten (W), molybdenum (Mo), tantalum (Ta), or titanium (Ti) with a preferable film thickness of 30 to 100 nm. In the semiconductor device 100, the gate electrode 110 was made of an alloy that contains tungsten as a chief element, and is formed to the film thickness of 50 nm.

The light-shielding layer 60 of the photodiode 50 is made of a multi-layered metal film composed of two metal layers. The material and film thickness of the first metal layer 111, which is formed on the glass substrate 101, are the same as those of the gate electrode 110. Therefore, in the semiconductor device 100, the first metal layer 111 of the light-shielding layer 60 is also made of an alloy that contains tungsten as a chief element and is formed to a film thickness of 50 nm. The second metal layer 113 formed on the first metal layer 111 is preferably made of a material having a higher conductivity than the first metal layer 111, such as aluminum (Al) or copper (Cu), and preferably has a film thickness of 50 to 200 nm. In the present embodiment, the second metal layer 113 was made of an alloy containing aluminum as a chief element and was formed to a film thickness of 100 nm. Therefore, in the semiconductor device 100, the film thickness of the gate electrode 110 of TFT 40 was 50 nm, and the film thickness of the light-shielding layer 60 of the photodiode 50 was 150 nm. The reason that the gate electrode 110 is formed to a smaller film thickness as discussed above will be described later. The second metal layer 113 is formed of a material of a high conductivity for the following reason. The gate wiring GL, which is electrically connected to the gate electrode 110 of the TFT 40, is formed in the same manufacturing process with the light-shielding layer 60. The gate wiring GL supplies to the gate electrode 110 the control signal provided from the gate driver. Therefore, the delay in the control signal due to the gate wiring GL has to be prevented by reducing the resistance value of the gate wiring GL through the use of a highly conductive material for the second metal layer 113.

A gate insulating film 128 is formed to cover the entirety of the glass substrate 101 including the gate electrode 110 and the light-shielding layer 60. The gate insulating film 128 may be constituted of a single type of insulating film, or may be formed of a multi-layer film in which multiple types of insulating films are layered. The film thickness of the gate insulating film 128 is preferably 50 to 300 nm, and more preferably 100 to 200 nm. For the gate insulating film 128, an insulating film made of silicon oxide (SiO₂), silicon nitride (SiNx), or silicon oxynitride (SiON) is suitably used.

On the gate insulating film 128, the island-shaped silicon layer 120 that will be the channel layer of TFT 40, and the island-shaped silicon layer 180 of the photodiode 50 are formed. As described below, the island-shaped silicon layers 120 and 180 are formed of polycrystalline silicon, which was formed by crystallizing an amorphous silicon with laser light radiation. The film thicknesses of the island-shaped silicon layers 120 and 180 are preferably 30 to 150 nm, and more preferably 50 to 100 nm. In the semiconductor device 100, the island-shaped silicon layers 120 and 180 were both set to 50 nm thick.

The island-shaped silicon layer 120 of TFT 40 includes a channel region 120c, which is formed above the gate electrode 110, LDD regions 120d, which are doped with an n-type impurity at a low concentration and are respectively disposed on the right and left sides of the channel region 120c, and a source region 120a and drain region 120b, which are doped with an n-type impurity at a high concentration and are disposed outside the LDD region 120d.

The crystals of the polycrystalline silicon that constitute the island-shaped silicon layer 120 of the TFT 40 may be granular crystals having large crystal grain diameters, but more preferably are lateral crystals that extend long in a certain direction. The size of the lateral crystals depends on the film thickness of the amorphous silicon. In the case of the semiconductor device 100, the longer sides of the lateral crystals are several μm, and the shorter sides are 0.5 to 1.0 μm. They are larger than the crystal grain diameters of 0.3 to 0.5 μm of polycrystalline silicon crystallized by radiating the excimer laser. Therefore, the mobility of the island-shaped silicon layer 120 constituted of the lateral crystals is increased, and so is the mobility of the TFT 40 having the island-shaped silicon layer 120 as the channel layer. In particular, if the direction of the long axis of the lateral crystals matches the direction of the channel length, the TFT 40 operates even faster. The method for growing the lateral crystals will be discussed below.

On the other hand, at the respective ends of the island-shaped silicon layer 180 of the photodiode 50, an n-type region 180a, which is doped with an n-type impurity at a high concentration, and a p-type region 180b, which is doped with a p-type impurity at a high concentration, are formed. An intrinsic region 180c is formed in the region sandwiched by the n-type region 180a and p-type region 180b. Thus, the photodiode 50 is a lateral type pin diode.

On top surfaces of the island-shaped silicon layers 120 and 180, a protective film 130 made of silicon oxide is formed. Further, a first interlayer insulating film 131 made of silicon nitride is formed to cover the entire glass substrate 101 including the protective film 130. The film thickness of the first interlayer insulating film 131 is preferably 100 to 400 nm. On the first interlayer insulating film 131, a second interlayer insulating film 132 made of silicon oxide is formed. The film thickness of the second interlayer insulating film 132 is preferably 200 to 600 nm.

For the TFT 40, a source electrode 140a and a drain electrode 140b that are electrically connected to the source region 120a and the drain region 120b, respectively, through the contact holes provided in the first interlayer insulating film 131 and the second interlayer insulating film 132 are formed. For the photodiode 50, a cathode electrode 190a and an anode electrode 190b that are electrically connected to the n-type region 180a and the p-type region 180b, respectively, through the contact holes provided in the first interlayer insulating film 131 and the second interlayer insulating film 132 are formed. To prevent any delay in the control signals or image signals, the source electrode 140a, the drain electrode 140b, the gate connection electrode 140c, the cathode electrode 190a, and the anode electrode 190b are made of a highly conductive metal such as aluminum or molybdenum. In the case of the semiconductor device 100, aluminum is used as the material of the electrodes.

A planarizing film 148 made of a photosensitive acrylic resin is formed to cover the entire glass substrate 101 including the TFT 40 and the photodiode 50. On the planarizing film 148, a pixel electrode 161 made of a transparent metal such as ITO (Indium Tin Oxide) is formed. The pixel electrode 161 is electrically connected to the drain electrode 140b of the TFT 40 through a contact hole in the planarizing film 148. On the other hand, for the photodiode 50, a recess 160 extending to the surface of the second interlayer insulating film 132 is formed above the intrinsic region 180c of the island-shaped silicon layer 180 to prevent the decline in the intensity of the light reflected against a finger or the like. The pixel electrode 161 covers the surface of the planarizing film 148 above the cathode electrode 190a, and extends to cover the inner surface of the recess 160 and to cover the surface of the planarizing film 148 above the anode electrode 190b. Further, on the pixel electrode 161 above the TFT 40, and on the pixel electrode 161 above the cathode electrode 190a and the anode electrode 190b of the photodiode 50, a black matrix 162 made of a light-shielding material such as chrome (Cr) is formed.

### 3. Method for Manufacturing a Semiconductor Device

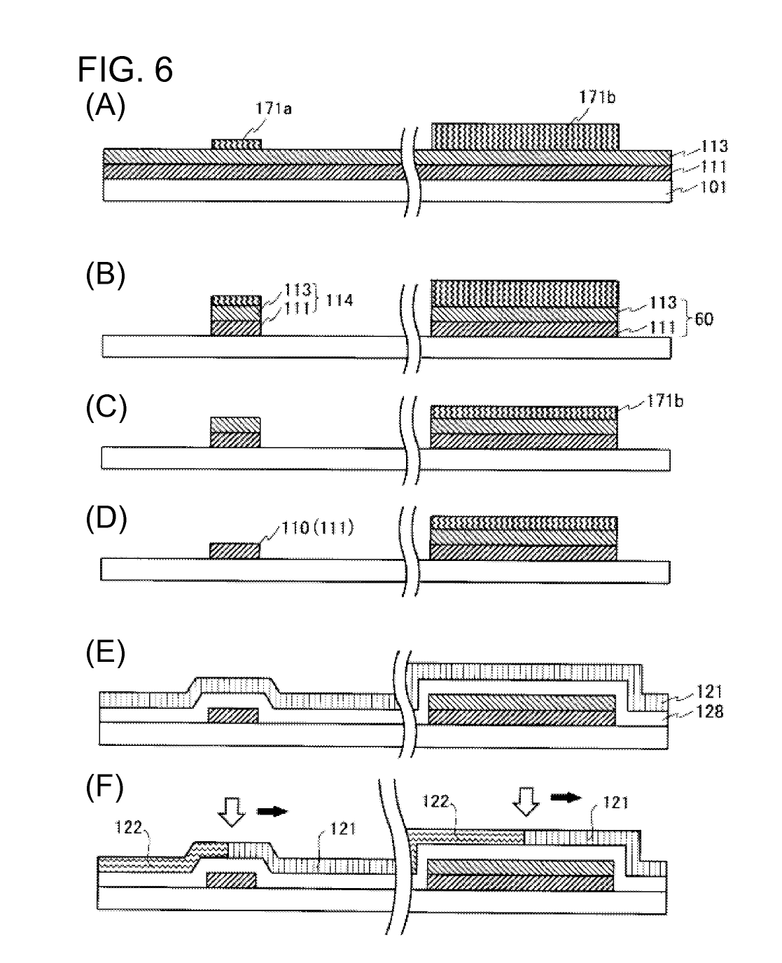

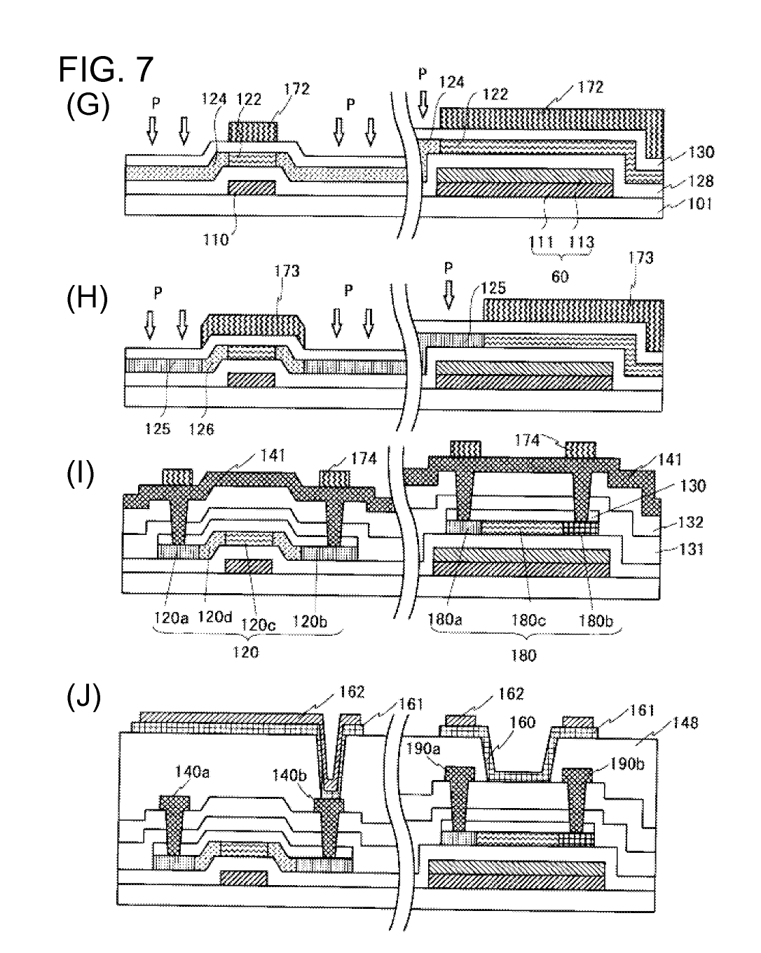

FIG. 6 and FIG. 7 are cross-sectional views showing manufacturing steps of the semiconductor device 100 of FIG. 5. In FIG. 6 and FIG. 7, the cross-sectional view taken along the line A-A of FIG. 4 is omitted. With reference to FIG. 6 and FIG. 7, a method for manufacturing the semiconductor device 100 is described. As shown in FIG. 6(A), on the glass substrate 101, with a sputtering method, a first metal layer 111 made of alloy containing tungsten as a chief element and having a film thickness of 50 nm is deposited. Next, on the first metal layer 111, a second metal layer 113 made of alloy containing aluminum as a chief element and having a film thickness of 100 nm is deposited.

On the second metal layer 113, a photoresist is applied to form a resist film (not shown), and the resist film is exposed using a half-tone mask to form resist patterns 171a and 171b of desired shapes. The half-tone mask includes not only the pattern constituted of a light-shielding section that fully blocks the exposure light but also includes the pattern constituted of a semi-transmissive section where slits or the like are provided to transmit a certain percentage of the exposure light.

The pattern for the gate wiring (not shown) of TFT 40 and the pattern for the light-shielding layer 60 of the photodiode 50 are constituted of a light-shielding section. A half-tone mask constituted of a semi-transmissive section is used in the pattern for the gate electrode 110. In this case, the exposure light is fully blocked in the region that will be the gate wiring and the light-shielding layer 60, and therefore, a resist pattern 171b having a large film thickness is formed. On the other hand, a portion of the exposure light is transmitted in the region that will be the gate electrode 110, and therefore a resist pattern 171a having a smaller film thickness than the resist pattern 171b is formed.

As shown in FIG. 6(B), with the dry etching using the resist patterns 171a and 171b as masks and a chlorine (Cl₂) gas as the etching gas, the second metal layer 113 made of an alloy containing aluminum as a chief element is patterned. Next, with the dry etching using a sulfur hexafluoride (SF₆) gas as the etching gas, the first metal layer 111 made of an alloy containing tungsten as a chief element is patterned. As a result, a light-shielding layer 60 of the photodiode 50 and the gate wiring of the TFT 40, and a protrusion 114 that will be the gate electrode 110 are formed.

As shown in FIG. 6(C), ashing is conducted using an oxygen (O₂) gas to remove the resist pattern 171a on the protrusion 114 and to expose the surface of the second metal layer 113. At this time, on the light-shielding layer 60 and the gate wiring, the resist pattern 171b, whose film thickness is now smaller due to the ashing, still remains.

As shown in FIG. 6(D), using the remaining resist pattern 171b as the mask, the second metal layer 113 of the protrusion 114 is removed with the wet etching. The wet etching is conducted using an etchant having a high selection ratio (the ratio of the etching speed on the alloy containing aluminum as a chief element relative to the etching speed on an alloy containing tungsten as a chief element). After that, the resist pattern 171b is peeled off. In order to wet-etch the second metal layer 113 made of an alloy containing aluminum as a chief element, an etchant containing acetic acid (CH₃COOH), phosphoric acid (H₃PO₄), and nitric acid (HNO₃) is used. Through this wet etching, a gate electrode 110 is formed. Alternatively, the second metal layer 113 may be removed by dry etching.

As shown in FIG. 6(E), with the plasma enhanced chemical vapor deposition method and using silane (SiH₄), ammonia (NH₃), and nitrous oxide (N₂O) as the material gas, a gate insulating film 128, which is made of a multi-layered film composed of a silicon oxide film layered over a silicon nitride film, is deposited to a film thickness of 100 to 200 nm to cover the entire glass substrate 101 including the gate electrode 110 of the TFT 40 and the light-shielding layer 60 of the photodiode 50. Next, on the gate insulating film 128, an amorphous silicon layer 121 is deposited to a film thickness of 50 nm with the plasma CVD method using silane and hydrogen as the material gas.

Because the gate insulating film 128 and the amorphous silicon layer 121 are both deposited with the plasma CVD method, they may be deposited sequentially by switching the material gases. In this case, after the gate insulating film 128 is deposited, the amorphous silicon layer 121 is deposited without exposing the surface of the gate insulating film 128 to the atmosphere. Contamination of the interface between the gate insulating film 128 and the amorphous silicon layer 121, therefore, can be prevented, and the fluctuation of the threshold voltage of the TFT 40 can be suppressed.

Next, annealing is conducted for about 1 to 2 hours in the nitrogen atmosphere at about 400° C. to remove the hydrogen contained in the amorphous silicon layer 121. As shown in FIG. 6(F), by irradiating the amorphous silicon layer 121 from which the hydrogen has been removed with the laser light, the amorphous silicon layer 121 is crystallized to form a polycrystalline silicon layer 122. The laser used is a continuous-wave laser called Nd:YVO₄ laser, which has a wavelength of 532 nm. The laser output was set to 11.5 W. The beam shape of the laser light is set to 0.1×2.0 mm, for example, for an elongated shape, and the laser light scans the surface of the amorphous silicon layer 121 horizontally. The scan speed of the laser light is preferably 300 to 500 mm/sec.

The amorphous silicon layer 121 in the region irradiated with the laser light fully melts, and furthermore, the gate electrode 110 is formed of the first metal layer 111, which is made of an alloy containing tungsten, a metal having a relatively small thermal conductivity of 174 W/m·K, as a chief element. A portion of the energy generated in the amorphous silicon layer 121 is provided to the gate electrode 110 through heat radiation. However, the thermal energy provided to the gate electrode 110 is not further transferred to the gate wiring easily, and therefore is not dissipated at the gate wiring easily. As a result, the amorphous silicon layer 121 maintains a high temperature for extended period of time, and the melted silicon cools down and is solidified slowly. Consequently, a polycrystalline silicon layer 122 composed of lateral crystals that have elongated shapes with long axes extending in the laser beam scan direction is formed.

In this case, the film thickness of the gate electrode 110 is 50 nm, which is very small. The slope of the amorphous silicon layer 121 due to the surface elevation created by the edge of the gate electrode 110 is, therefore, moderate. Consequently, when the amorphous silicon layer 121 fully melts, the melted silicon is less likely to flow towards the glass substrate 101 side, and once the silicon is crystallized to become the polycrystalline silicon layer 122, it is less likely to break over the edge of the gate electrode 110. On the other hand, the film thickness of the light-shielding layer 60 of the photodiode 50 is 150 nm, which is large. Therefore, over the edges of the light-shielding layer 60, the slope of the amorphous silicon layer 121 formed to cover the light-shielding layer 60 is steep. As a result, when the amorphous silicon layer 121 fully melts, the melted silicon flows to the glass substrate 101 side, and once the silicon is crystallized to become the polycrystalline silicon layer 122, it tends to break at the edge of the light-shielding layer 60. However, in the photodiode 50, unlike the case of the TFT 40, the polycrystalline silicon layer 122 outside the light-shielding layer 60, does not constitute the island-shaped silicon layer 180. Therefore, in the photodiode 50, any breakage of the polycrystalline silicon layer 122 over the edge of the light-shielding layer 60 does not cause a problem.

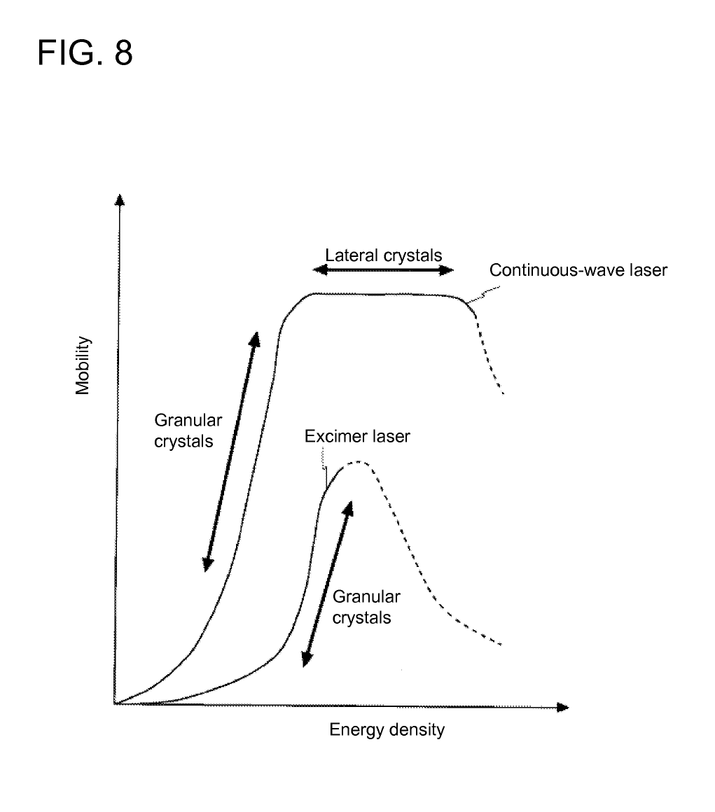

FIG. 8 shows the mobility of polycrystalline silicon layers obtained by crystallizing the amorphous silicon layer using the continuous-wave laser or the excimer laser. The horizontal axis of FIG. 8 represents the energy density of the radiated laser light, and the vertical axis represents the mobility of the polycrystalline silicon layer crystallized by laser annealing. As shown in FIG. 8, when the excimer laser light is radiated, the mobility of the polycrystalline silicon layer increases as the energy density increases until the mobility reaches the maximum level when the energy density reaches a certain value. As the energy density increases further, the mobility decreases. Therefore, it is understood that if the amorphous silicon layer is crystallized using the excimer laser, the mobility changes significantly by changing the energy density. Consequently, it is very difficult to obtain a particular mobility of the polycrystalline silicon layer by adjusting the laser light energy density for silicon crystallization. The crystal grains of the polycrystalline silicon layer crystallized with the excimer laser are granular crystals.

On the other hand, as the energy density of the continuous-wave laser light increases, the mobility of the resulting polycrystalline silicon layer increases accordingly. This polycrystalline silicon layer is also composed of granular crystals, but the crystal grain diameters are larger than in the case that the excimer laser is used. The mobility of the polycrystalline silicon layer, therefore, is greater than the mobility of the polycrystalline silicon layer crystallized using the excimer laser. As the energy density increases, the mobility reaches a certain value. Further increase in the energy density does not significantly change the mobility beyond this point and the certain value of mobility is roughly maintained. Within the range where the change in the energy density does not significantly change the mobility from the certain value, particular mobility of the polycrystalline silicon layer can easily be obtained by adjusting the laser light energy density. The crystal grains of the polycrystalline silicon layer obtained by crystallizing with laser light at any energy density within the range in which a change in the energy density does not result in a significant change in the mobility will become lateral crystals.

Thus, the amorphous silicon layer can easily be converted to the polycrystalline silicon layer composed of lateral crystals by using continuous-wave laser and by increasing the energy density beyond a certain level. This way, TFTs that operate faster can be obtained. Also, the range of energy densities necessary to make a polycrystalline silicon layer composed of lateral crystals is wide. As a result, even if the film thickness of the amorphous silicon layer is inconsistent or even if there exist amorphous silicon layer under which the gate electrode is present and amorphous silicon layer under which the gate electrode is not present, which may occur when an amorphous silicon layer is deposited on a large glass substrate, for example, by using the continuous-wave laser, regardless of the inconsistency in the film thickness or the presence or absence of the gate electrode underneath, the amorphous silicon layer can be converted to a polycrystalline silicon layer composed of lateral crystals. In the case of the semiconductor device 100, an excimer laser such as the xenon chloride (XeCl) excimer laser or the krypton fluoride (KrF) excimer laser may be used instead of the continuous-wave laser to convert the amorphous silicon layer into a polycrystalline silicon layer composed of granular crystals.

As shown in FIG. 7(G), a protective film 130 made of silicon oxide having a film thickness of 50 to 100 nm is deposited to cover the polycrystalline silicon layer 122 with the plasma CVD method. Next, in order to control the threshold voltage of the TFT 40, the entire surface of the polycrystalline silicon layer 122 is doped with phosphorus (P), an n-type impurity, or boron (B), a p-type impurity, through the protective film 130 with the ion implantation method or the ion doping method. Then, on the protective film 130, a resist film (not shown) is formed using the photolithography technology. Next, using the gate electrode 110 and the light-shielding layer 60 as masks, exposure is conducted from the bottom side of the glass substrate 101 (the bottom side of FIG. 7(G)). In this case, because the gate electrode 110 and the light-shielding layer 60 block the exposure light, a resist pattern 172 is formed in a manner of self-alignment on the gate electrode 110 and the light-shielding layer 60. Using the resist pattern 172 as the mask, phosphorus is doped into the polycrystalline silicon layer 122 through the protective film 130 at a low concentration with the ion plantation method or the ion doping method. As a result, a low concentration region 124 (n-region 124) is formed in the polycrystalline silicon layer 122 where the phosphorus has been implanted. Then, the resist pattern 172 is peeled off.

As shown in FIG. 7(H), using the photolithography technology, on the protective film 130 disposed over the gate electrode 110, a resist pattern 173, which is larger than the resist pattern 172, is formed. Also, the resist pattern 173 is formed over the region of the island-shaped silicon layer 180 of the photodiode 50 that will be the intrinsic region 180c or the p-type region 180b. Next, using the resist pattern 173 as the mask, with the ion plantation method or the ion doping method, phosphorus is doped into the polycrystalline silicon layer 122 at a high concentration through the protective film 130. As a result, in the TFT 40, the region doped with phosphorus at a high concentration becomes an n-type high concentration region 125, and the region sandwiched by the n-type high concentration region 125 and the channel region 120c becomes an LDD region 120d. In the photodiode 50, the region of the polycrystalline silicon layer 122 that is doped with phosphorus at a high concentration becomes an n-type high concentration region 125.

Next, in the manner shown in FIG. 7(H), by forming a resist pattern (not shown) and doping boron at a high concentration using the resist pattern as the mask with the ion implantation method or the ion doping method, a p-type high concentration region of the p-channel type TFT (not shown) and a p-type high concentration region 180b of the photodiode 50 are formed. The region of the photodiode 50 sandwiched by the n-type high concentration region 125 and the p-type high concentration region will become the intrinsic region 180c. Then, annealing is conducted to activate the doped phosphorus and boron.

As shown in FIG. 7(I), using the photolithography method, a resist pattern of a desired shape (not shown) is formed on the protective film 130. By conducting the dry-etching using the resist pattern as the mask and the etching gas of carbon tetrafluoride (CF₄), an island-shaped silicon layer 120 of the TFT 40 and an island-shaped silicon layer 180 of the photodiode 50, which are separate from each other, are formed. Thus, in the TFT 40, a source region 120a and a drain region 120b are formed at the respective ends of the island-shaped silicon layer 120. In the photodiode 50, an n-type region 180a and a p-type region 180b are formed at the respective ends of the island-shaped silicon layer 180.

Next, with the plasma CVD method, the low pressure CVD method, or the sputtering method, a first interlayer insulating film 131 and a second interlayer insulating film 132 are formed in this order to cover the island-shaped silicon layers 120 and 180 and the protective film 130 disposed over the island-shaped silicon layers. The first interlayer insulating film 131 is made of silicon nitride having a film thickness of 100 to 400 nm, and the second interlayer insulating film 132 is made of silicon oxide having a film thickness of 200 to 600 nm. Further, the glass substrate 101 with the TFT 40 and the photodiode 50 formed thereon is annealed at 300 to 400° C. in the nitrogen gas atmosphere or in vacuum to diffuse the hydrogen contained in the first interlayer insulating film 131 to the island-shaped silicon layers 120 and 180. Thus, the dangling bonds in the island-shaped silicon layer are terminated. This makes the interface states less likely to occur in the island-shaped silicon layer 120 of the TFT 40 and in the island-shaped silicon layer 180 of the photodiode 50. As a result, characteristics such as the threshold voltage are improved.

Next, contact holes that respectively reach the source region 120a, the drain region 120b, the n-type region 180a, the p-type region 180b, and the gate electrode 110 are formed in the first interlayer insulating film 131 and the second interlayer insulating film 132 with the dry etching. Then, with the sputtering method, an aluminum film 141 is deposited over the entire glass substrate 101 including the second interlayer insulating film 132. Next, on the aluminum film 141, a resist pattern 174 of a desired shape is formed with the photolithography method, and the aluminum film 141 is dry-etched using the resist pattern 174 as the mask. As a result, a source electrode 140a electrically connected to the source region 120a, a drain electrode 140b electrically connected to the drain region 120b, a cathode electrode 190a electrically connected to the n-type region 180a, an anode electrode 190b electrically connected to the p-type region 180b, and a gate connection electrode (not shown) electrically connected to the gate electrode 110 are formed. Alternatively, the aluminum film 141 may be wet-etched.

As shown in FIG. 7(J), a planarizing film 148 made of a photosensitive acrylic resin is deposited over the entire surface of the glass substrate 101. The planarizing film 148 is exposed and developed to form a contact hole that reaches the drain electrode 140b. At the same time, above the intrinsic region 180c of the photodiode 50, a recess 160 that reaches the surface of the second interlayer insulating film 132 is formed. Next, by the sputtering method, a transparent metal film (not shown) such as ITO is deposited. The transparent metal film is etched to form a pixel electrode 161 that is electrically connected to the top surface of the drain electrode 140b through the contact hole provided in the planarizing film 148. The pixel electrode 161 is further formed to cover the surface of the planarizing film 148 located above the cathode electrode 190a, and extends to cover the inner surface of the recess 160 and to cover the surface of the planarizing film 148 located above the anode electrode 190b. Over the surface of the pixel electrode 161 of the TFT 40, the surface of the cathode electrode 190a of the photodiode 50, and the surface of the pixel electrode 161 located above the anode electrode 190b, a black matrix 162 made of chrome or the like is formed. This way, a semiconductor device 100 including the TFT 40 that functions as the switching element of the pixel formation section and the photodiode 50 that functions as a touch sensor is manufactured.

The TFT 40 included in the semiconductor device 100 of the present embodiment was described as the TFT that functions as the switching element of the pixel formation section. However, the TFT 40 may be a TFT constituting the driver circuit of the source driver, the gate driver, or the like.

### 3. Effects

In the TFT 40 included in the semiconductor device 100, the island-shaped silicon layer 120 including the channel layer 120c is made of a polycrystalline silicon. Therefore, the mobility of the channel layer 120c is high, and the TFT 40 can operate at a high speed. Also, because the breakage of the island-shaped silicon layer 120, which is made of a polycrystalline silicon, at the edge of the gate electrode 110 can be prevented, the TFT 40 can operate reliably. In the photodiode 50, because the light entering the glass substrate 101 from the surface on the side opposite to the surface on which the TFT 40 is formed can be blocked by the light-shielding layer 60, detection sensitivity of the photodiode 50 that functions as a touch sensor can be increased.

The gate wiring GL connected to the gate electrode 110 of the TFT 40 is formed of a multi-layered metal film where a metal layer having the same film thickness and made of the same material as the second metal layer 113 is disposed on a metal layer having the same film thickness and made of the same material as the first metal layer 111. Therefore, the delay in signals provided to the gate electrode 110 through the gate wiring GL can be prevented.

By using the TFT 40 of the semiconductor device 100 as the thin film transistor included in the pixel formation section 31 formed in the display region 21 of the liquid crystal panel 10 and by using the photodiode 50 as the photodiode, fast TFT operation and increased photodiode detection sensitivity can be obtained. As a result, the liquid crystal panel 10 can be used as a touch panel.

In the embodiment described above, the TFT 40 is also referred to as “first semiconductor element,” and the photodiode 50 is also referred to as “second semiconductor element.” The gate electrode 110 of the TFT 40 is also referred to as “first structure” or “first layer,” and the island-shaped silicon layer 120 of the TFT 40 is also referred to as “polycrystalline silicon layer.” The light-shielding layer 60 of the photodiode 50 is also referred to as “second structure,” and the first metal layer 111 of the photodiode 50 is also referred to as “second layer,” and the second metal layer 113 is also referred to as “third layer.”

### 4. Modification Examples

### 4.1 Modification Example 1

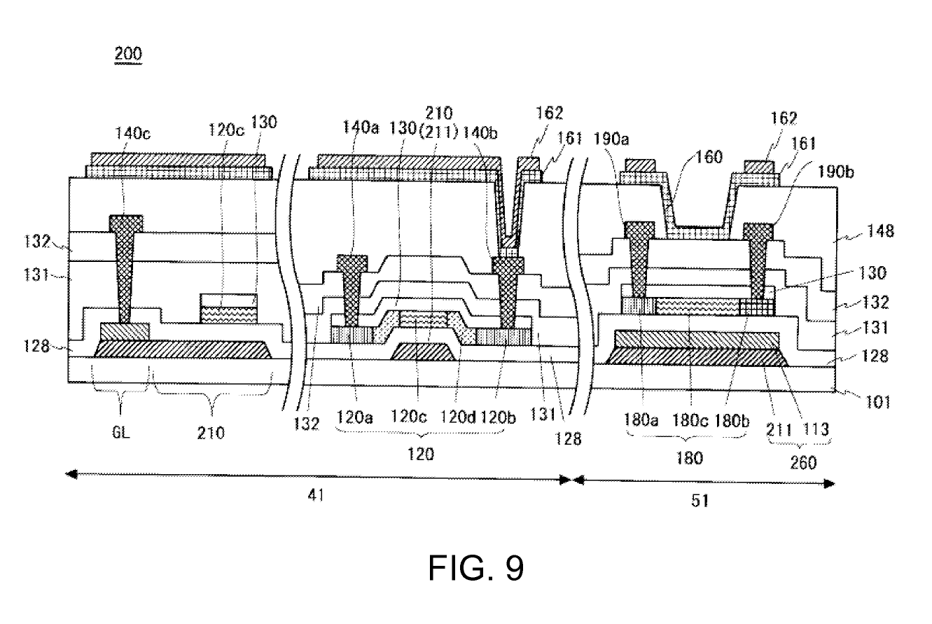

When the amorphous silicon layer fully melts to form the polycrystalline silicon layer, to prevent the amorphous silicon layer from breaking over the edges of the gate electrode, the edges of the gate electrode may be tapered instead of making the film thickness of the gate electrode 110 small as in the case of the semiconductor device 100 shown in FIG. 5. FIG. 9 is a cross-sectional view showing the configuration of the semiconductor device 200 including the TFT 41 according to Modification Example 1 of the present invention, whose gate electrode 210 has tapered edges. Of the constituting elements of the semiconductor layer 200 shown in FIG. 9, those identical to the constituting elements of the semiconductor device 100 shown in FIG. 5 are provided with the same reference characters, and descriptions of those elements are omitted.

As shown in FIG. 9, the edges of the gate electrode 210 are tapered. The amorphous silicon layer covering the gate electrode 210 therefore has a moderate slope at the edge of the gate electrode 210. When the amorphous silicon layer is irradiated with the laser light and fully melts, the melted silicon is less likely to flow towards the glass substrate 101. Consequently, the island-shaped silicon layer 120 formed of the polycrystalline silicon layer, which was made from the solidification of the melted silicon, becomes less likely to break at the edges of the gate electrode 210. Also, when the edges of the gate electrode 210 are tapered, simultaneously the edges of the first metal layer 211 constituting the light-shielding layer 260 acquire a tapered shape. However, the island-shaped silicon layer 180 is formed on the light-shielding layer 260. Therefore, as discussed above, no problem is posed even if the polycrystalline silicon layer breaks at an edge of the light-shielding layer 260. Therefore, the edges of the light-shielding layer 260 do not have to be tapered. In this specification, the level difference between the surface of the glass substrate 101 and the surface of the gate electrode is called “surface elevation” not only when the edge of the gate electrode is approximately perpendicular to the glass substrate 101 as in the case of the gate electrode 110 shown in FIG. 5, but also when the edge is tapered to form a certain angle against the glass substrate 101 as in the case of the gate electrode 210 shown in FIG. 9.

In the case of the semiconductor device 200, the angle formed between the tapered edge of the gate electrode 210 and the glass substrate 101 is preferably 10 to 50 degrees. If the taper angle is larger than 50 degrees, the melted silicon tends to flow down and the breakage is likely to occur. On the other hand, if the taper angle is smaller than 10 degrees, the melted silicon is less likely to flow down, but the process of forming the taper becomes more challenging.

Next, a method for tapering the edges of the gate electrode 210 is described. In the manufacturing process illustrated in FIG. 6(B), the second metal layer 113 made of an alloy containing aluminum as a chief element is patterned with dry etching using the resist pattern 171a as the mask. Next, the first metal layer 111 made of an alloy containing tungsten as a chief element is patterned with wet etching. For the wet etching, an etchant containing nitric/hydrofluoric acid, hydrofluoric acid (HF), hydrogen peroxide (H₂O₂) or the like as a chief element is used. In this case, the first metal layer 111 is wet-etched starting at the edge of the bottom surface of the second metal layer 113. The wet etching proceeds isotropically in the downward and sideward directions. As a result, the second metal layer 113 hangs over the first metal layer 111, and the first metal layer 111 becomes the first metal layer 211 with tapered sides. Further, in a manner similar to the process shown in FIG. 6(C), the resist pattern 171a on the protrusion 114 that will be the gate electrode 115 is removed by ashing to expose the surface of the second metal layer 113. Then, the second metal layer 113 made of an alloy containing aluminum as a chief element is removed by wet etching. As a result, a gate electrode 210 made only of the first metal layer 211 is formed, and the sides of the gate electrode 210 are tapered.

If the film thickness of the gate electrode 210 is small, the edge of the electrode does not have to be tapered to prevent the breakage of the island-shaped silicon layer 120 at the edge of the gate electrode 210 as described above. However, the breakage of the island-shaped silicon layer 120 can be prevented more reliably by not only making the film thickness of the gate electrode 210 small, but also by tapering the edges of the electrode.

### 4.2 Modification Example 2

In the semiconductor device 100 shown in FIG. 4, the light-shielding layer 60 of the photodiode 50 is formed by patterning the multi-layered metal film in which the second metal layer 113 made of an alloy containing aluminum as a chief element is layered over the first metal layer 111 made of an alloy containing tungsten as a chief element. However, the light-shielding layer may also be formed by patterning a multi-layered metal film composed of three or more metal layers including a first metal layer 111 made of the same material and having the same film thickness as the gate electrode 110 of the TFT 40. In this case, because the film thickness of the light-shielding layer becomes larger, the light projected directly from backlight light source can be more effectively blocked from entering the photodiode, and therefore the light that is supposed to be detected, i.e., the light projected from the backlight light source and reflected by a finger or the like, can be detected with a higher sensitivity.

The light-shielding layer of the photodiode may also be formed of a metal layer made only of an alloy containing tungsten as a chief component. In this case, the film thickness of the metal layer must be large enough (150 to 300 nm, for example) so that the metal layer can sufficiently serve as the light-shielding layer. That is, the film thickness must be at least as large as the combined thickness of first metal layer 111 and the second metal layer 113 in the embodiment described above. In this case, deposition process can be simplified, because the film thickness of only one kind of metal layer, instead of two kinds of metal layers, is adjusted for deposition.

Also, in order to reduce the film thickness of the gate electrode of the TFT, of the metal layer that was formed thick, the region that will be the gate electrode must be etched to reduce its film thickness. However, it is difficult to make the dry-etched surface of the metal layer smooth, and therefore the surface tends to be uneven. The uneven surface of the metal layer poses the problem that the size of the crystal grains of the polycrystalline silicon layer, which was crystallized with laser annealing, tends to become inconsistent. Therefore, the film thickness of the metal layer of the protrusion that will become the gate electrode is preferably reduced by wet-etching. For the wet-etching of the metal layer made of an alloy containing tungsten as a chief element, an etchant containing nitric/hydrofluoric acid, hydrofluoric acid, hydrogen peroxide, or the like as a chief element is used.

### 4.3 Modification Example 3

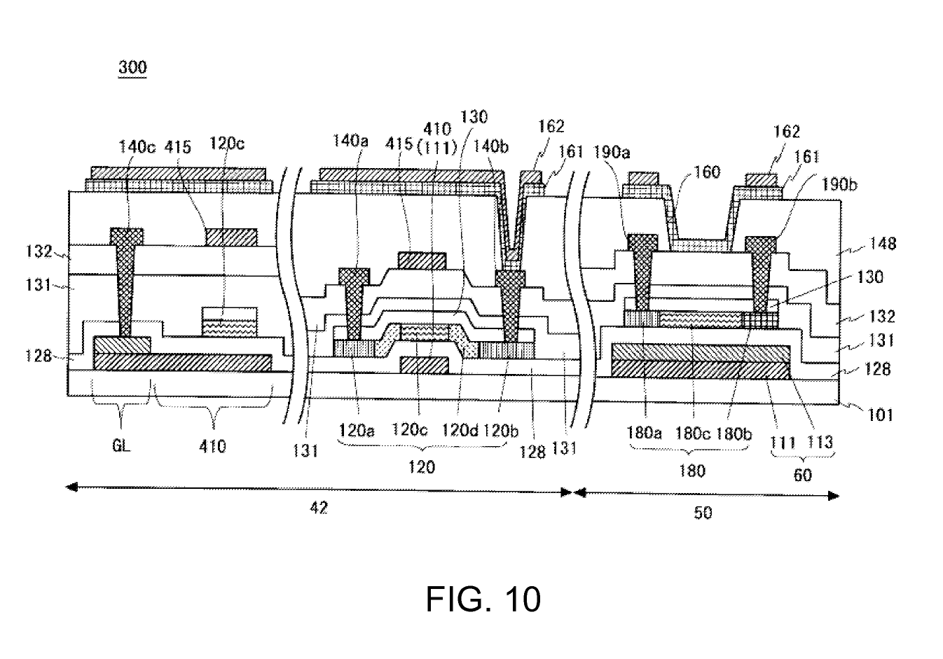

In the semiconductor device 100 shown in FIG. 5, the gate electrode 110 of the TFT 40 is formed only on the glass substrate 101. However, instead of the TFT 40, a double gate type TFT, which has gate electrodes over and under the island-shaped silicon layer 120, may be formed. FIG. 10 is a cross-sectional view showing the configuration of the semiconductor device 300 according to Modification Example 3 of the present invention, in which a double gate type TFT 42 is included. Of the constituting elements of the semiconductor device 300 shown in FIG. 10, those identical to the constituting elements of the semiconductor device 100 shown in FIG. 5 are provided with the same reference characters, and descriptions of those elements are omitted.

As shown in FIG. 10, in the double gate type TFT 42, as in the case of the TFT 40 of the semiconductor device 100 shown in FIG. 5, not only a first gate electrode 410 is formed on the glass substrate 101, but also a second gate electrode 415 is formed on the second interlayer insulating film 132 that faces the channel region 120c. In the double gate type TFT 42, the back gate effect can be obtained by maintaining the voltage applied to the second gate electrode 415 to a prescribed level. The threshold voltage, therefore, can be stabilized. Also, the threshold voltage can be changed by adjusting the voltage applied to the second gate electrode 415. In this case, the threshold voltage can easily be changed by simply adjusting the voltage applied to the second gate electrode 415, without having to change the manufacturing process of the semiconductor device 300.

The second gate electrode 415 of the double gate type TFT 42 is formed simultaneously with the source electrode 140a and the drain electrode 140b by patterning the metal film such as the aluminum film deposited to form the source electrode 140a and the drain electrode 140b. As a result, all that is needed is to use a different mask in the method for manufacturing in the embodiment described above, instead of the mask for patterning the source electrode 140a, drain electrode 140b, and the like illustrated in FIG. 7(I). There is no need to add any new manufacturing process.

### 4.4 Modification Example 4

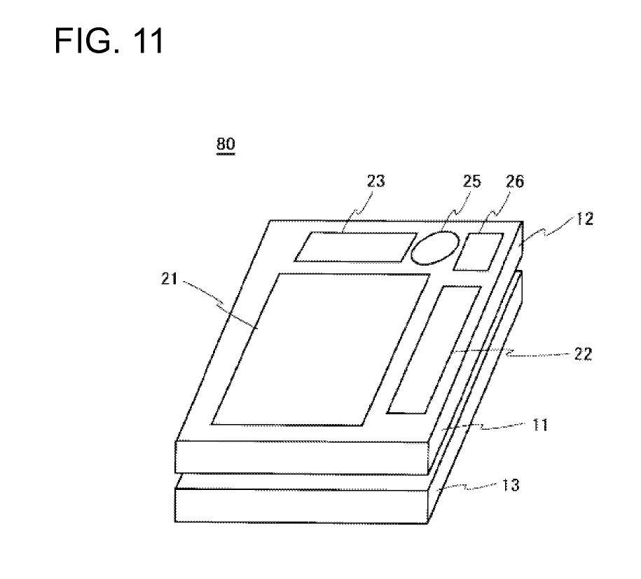

In FIG. 1, a photodiode 50 is disposed in each of the pixel formation sections, and is used as a touch sensor. However, the photodiode may also be disposed in the frame region of the TFT substrate 11 and be used as an ambient light sensor that controls the luminance of the backlight light source 13 according to the intensity of external light. FIG. 11 is a perspective view showing the configuration of a liquid crystal panel 80 according to Modification Example 4 of the present invention, in which a photodiode 25 that functions as an ambient sensor is included. Of the constituting elements of the liquid crystal panel 80 shown in FIG. 11, those identical to the constituting elements of the liquid crystal panel 10 shown in FIG. 1 are provided with the same reference characters, and descriptions of these elements are omitted.

As shown in FIG. 11, in the liquid crystal panel 80, a photodiode 25 is disposed in the frame region of the TFT substrate 11, and a backlight control circuit 26 is disposed adjacent to the photodiode 25. The backlight control circuit 26 adjusts the intensity of the light from the backlight light source 13 depending on the output of the photodiode 25. This way, the image luminance can be adjusted according to the external light intensity. In this specification, the touch sensor and the ambient sensor are collectively called “light sensor.” Further, the touch sensor is referred to as “first light sensor,” and the ambient sensor is referred to as “second light sensor.”

### 4.5 Modification Example 5

In the description of the semiconductor device 100 shown in FIG. 4, it is the photodiode 50 including the light-shielding layer 60 that is formed on the glass substrate 101, together with the bottom gate type TFT 40. However, in order to prevent the signal delay, the semiconductor element formed together with the bottom gate type TFT 40 may be a TFT that has a wiring layer having a low wiring resistance. Here, in a manner similar to the light-shielding layer 60, a multi-layered metal film in which a first metal layer and a second metal layer having a higher conductivity than the first metal layer are layered together is used to form a wiring layer.

### 4.6 Modification Example 6

In the description above, the island-shaped silicon layer 120 made of a polycrystalline silicon is formed to cover the surface elevation at the edge of the gate electrode 110 made of a conductive material such as a metal. However, the island-shaped silicon layer 120 may also be formed to cover the surface elevation at the edge of the structure made of an insulating material.

In the description above, the semiconductor device 100 shown in FIG. 4 is used in the TFT substrate 11 of an active matrix type liquid crystal display device. However, the semiconductor device 100 may also be used in TFT substrates of active matrix type organic EL (Electro-Luminescence) display devices.

### INDUSTRIAL APPLICABILITY

The present invention is suitable for display devices such as active matrix type liquid crystal display devices having a touch-panel feature or liquid crystal display devices that can adjust the intensity of the light from the backlight light source using the ambient sensor.

### DESCRIPTION OF REFERENCE CHARACTERS

10 wiring configuration
11 TFT substrate
22 gate driver
23 source driver
25 photodiode (ambient sensor)
26 backlight control circuit
31 pixel formation section
40, 41 bottom gate type thin film transistor
42 double gate type thin film transistor
50, 51 photodiode (touch sensor)
60 light-shielding layer
100, 200, 300 semiconductor device
101 glass substrate (insulating substrate)
110, 210, 410, 415 gate electrode
111,211 first metal layer
113 second metal layer
120 island-shaped silicon layer (of TFT)
180 island-shaped silicon layer (of photodiode)

1. A semiconductor device comprising at least a first semiconductor element and a second semiconductor element that is different from said first semiconductor element, both formed on a same insulating substrate,
wherein said first semiconductor element comprises:
a first structure having a surface elevation and constituted of a first layer; and
a polycrystalline semiconductor layer covering at least the surface elevation of said first structure,
wherein the second semiconductor element comprises a second structure including a second layer made of the same material as said first layer, the second structure being thicker than said first structure, and
wherein the surface elevation of said first structure is such that said polycrystalline semiconductor layer is formed without any breakage.

2. The semiconductor device according to claim 1, wherein the surface elevation of said first structure has a tapered edge.

3. The semiconductor device according to claim 1,
wherein said first semiconductor element is a bottom gate type thin film transistor, said first structure is a gate electrode of said bottom gate type thin film transistor, and said polycrystalline semiconductor layer is a channel layer of said bottom gate type thin film transistor, and
wherein said second semiconductor element is a light sensor, and
wherein said second structure is a light-shielding layer that blocks light entering through a surface of said insulating substrate on which said bottom gate type thin film transistor is formed.

4. The semiconductor device according to claim 3,
wherein said light-shielding layer is constituted only of said second layer, and
wherein the film thickness of said second layer is larger than the film thickness of said gate electrode.

5. The semiconductor device according to claim 3,
wherein said light-shielding layer is constituted of a plurality of layers including said second layer, and
wherein the film thickness of said second layer is equal to the film thickness of said gate electrode.

6. The semiconductor device according to claim 3, wherein said channel layer is a polycrystalline semiconductor layer that includes lateral crystals whose direction of long axis matches the direction of channel length.

7. The semiconductor device according to claim 3, wherein said light sensor is a lateral type pin photodiode.

8. The semiconductor device according to claim 3, further comprising a wiring connected to the gate electrode of said thin film transistor, wherein said wiring includes a third layer disposed on a top surface of said first layer and made of a material with a conductivity higher than that of said first layer.

9. A display device comprising a plurality of pixel formation sections disposed on an insulating substrate, each of said pixel formation sections having the semiconductor device according to claim 3,
wherein each of said plurality of pixel formation sections includes:
a pixel electrode;
a thin film transistor that applies a voltage on said pixel electrode when being switched from OFF state to ON state; and
a first light sensor that receives light entering said pixel formation section, and
wherein said thin film transistor and said first light sensor are said first semiconductor element and said second semiconductor element, respectively.

10. The display device according to claim 9, further comprising a driver circuit that drives said pixel formation sections, wherein said driver circuit is constituted of said first semiconductor elements.

11. The display device according to claim 9, further comprising:
a backlight light source;
a second light sensor that is disposed outside a display region in which said plurality of pixel formation sections are formed, the second light sensor detecting external light intensity; and
a backlight control circuit that controls a luminance of the backlight light source based on an output from said second light sensor,
wherein said second light sensor is said second semiconductor element.

12. A method for manufacturing a semiconductor device in which a bottom gate type thin film transistor and a light sensor having a light-shielding layer are formed on a same insulating substrate, comprising:
depositing a first conductive layer on said insulating substrate;
depositing a second conductive layer on said first conductive layer;
forming a first resist pattern in a region on said second conductive layer that will be a gate electrode, and forming a second resist pattern having a larger film thickness than said first resist pattern in a region on said second conductive layer that will be a light-shielding layer by conducting an exposure using a halftone mask;
forming said light-shielding layer by etching said second conductive layer and said first conductive layer in this order using said first and second resist patterns;
exposing a surface of said second conductive layer, which was covered with said first resist pattern, by reducing the film thicknesses of said first and second resist patterns simultaneously; and
forming said gate electrode by removing said second conductive layer the surface of which has been exposed.

13. The method for manufacturing a semiconductor device according to claim 12, further comprising:
forming an amorphous semiconductor layer to cover said gate electrode and said light-shielding layer;
forming a polycrystalline semiconductor layer by first melting said amorphous semiconductor layer by radiating continuous-wave laser light and then solidifying the melted amorphous semiconductor layer; and
patterning said polycrystalline semiconductor layer to form a channel layer of the thin film transistor that covers the gate electrode and a semiconductor layer of said light sensor over said light-shielding layer simultaneously.
